(19) United States
(12) Patent Application Publication
(10) Pub. No.: US 2025/0048840 A1
(43) Pub. Date: Feb. 6, 2025

(54) DISPLAY DEVICE AND METHOD OF MANUFACTURING DISPLAY DEVICE

(71) Applicant: Samsung Display Co., Ltd., Yongin-Si (KR)

(72) Inventors: Sang Ho LEE, Yongin-si (KR); Hee Woon IM, Yongin-si (KR); Yool Guk KIM, Yongin-si (KR); Ji Yoon KIM, Yongin-si (KR); Hyeon Sik KIM, Yongin-si (KR)

(21) Appl. No.: 18/407,446

(22) Filed: Jan. 9, 2024

(30) Foreign Application Priority Data
Jul. 31, 2023 (KR) 10-2023-0099311

(51) Int. Cl. H10K 59/122; H10K 59/12; H10K 59/80

(52) U.S. Cl. CPC H10K 59/122; H10K 59/1201; H10K 59/80515; H10K 59/873

(57) ABSTRACT

According to an embodiment of the disclosure, a display device is provided. The display device includes a base layer including a display area and a peripheral area, a light emitting element disposed in the display area and including a first electrode, a second electrode, and a light emitting part disposed between the first electrode and the second electrode, an electrode disconnection member disposed in the peripheral area, and an electrode portion disposed adjacent to the electrode disconnection member. The electrode disconnection member includes a reverse-taper member surrounding an area in a plan view. The reverse-taper member includes an inner edge facing the area. The electrode portion includes a first electrode portion disposed in the area and a second electrode portion disposed on an upper surface of the reverse-taper member along the inner edge. The first electrode portion and the second electrode portion are physically spaced apart from each other.

This application claims priority to and benefits of Korean patent application No. 10-2023-0099311 under 35 U.S.C. § 119, filed on Jul. 31, 2023, in the Korean Intellectual Property Office, the entire content of which is incorporated herein by reference.

### BACKGROUND

### 1. Field

The present disclosure relates to a display device and a method of manufacturing the display device.

### 2. Description of the Related Art

Recently, as interest in an information display increases, research and development on a display device are being continuously conducted.

Meanwhile, in order to secure device reliability of the display device, necessity for preventing a moisture permeation issue or the like exists. In order to prevent the moisture permeation issue, a method of forming a moisture permeation prevention structure may be considered.

### SUMMARY

An object of the present disclosure is to provide a display device and a method of manufacturing the display device, which may improve device reliability by reducing a moisture permeation risk.

An object of the present disclosure is to provide a display device and a method of manufacturing the display device, which may reduce a process cost by simplifying process equipment.

According to an embodiment of the disclosure, a base layer including a display area and a peripheral area surrounding at least a portion of the display area, a light emitting element disposed on the base layer in the display area and including a first electrode, a second electrode, and a light emitting part disposed between the first electrode and the second electrode, an electrode disconnection member disposed on the base layer in the peripheral area, and an electrode portion disposed adjacent to the electrode disconnection member. The electrode disconnection member may include a reverse-taper member and may have a shape surrounding an area in a plan view. The reverse-taper member may include an inner edge facing the area. The electrode portion may include a first electrode portion disposed in the area and a second electrode portion disposed on an upper surface of the reverse-taper member along the inner edge. The first electrode portion and the second electrode portion may be physically spaced apart from each other.

According to an embodiment, the display device may further include an outer capping layer disposed on the electrode portion. The light emitting element may further include a capping layer disposed on the second electrode and including a same material as the outer capping layer. At least a portion of the outer capping layer and the second electrode portion may expose at least a portion of the upper surface of the reverse-taper member.

According to an embodiment, the display device may further include an outer encapsulation layer disposed on the outer capping layer, and an encapsulation layer disposed on the capping layer in the display area and including a same material as the outer encapsulation layer. The outer encapsulation layer may expose at least a portion of the upper surface of the reverse-taper member and cover a side surface of the reverse-taper member facing the area.

According to an embodiment, the electrode disconnection member may include a plurality of electrode disconnection members. The plurality of electrode disconnection members may form an electrode disconnection area surrounding the display area.

According to an embodiment, the plurality of electrode disconnection members may be sequentially arranged on a first direction and a second direction different from the first direction.

According to an embodiment of the disclosure, a display device may include a base layer including a display area and a peripheral area surrounding at least a portion of the display area, a light emitting element disposed on the base layer in the display area and including a first electrode, a second electrode, and a light emitting part disposed between the first electrode and the second electrode, and an electrode disconnection member disposed on the base layer in the peripheral area. The electrode disconnection member may include a base electrode and a protruding insulating layer disposed on the base electrode. The base electrode may include a first base electrode and a second base electrode spaced apart each other. The protruding insulating layer may include a first protruding insulating layer disposed on the first base electrode and a second protruding insulating layer on the second base electrode. At least a portion of the protruding insulating layer may protrude from the base electrode in a plan view. A separation area having a closed-loop structure may be formed between the first base electrode and the second base electrode.

According to an embodiment, the light emitting element may further include a capping layer disposed on the second electrode. The display device may further include an encapsulation layer disposed on the capping layer. The encapsulation layer may be disposed in the display area without being disposed in an electrode disconnection area where the electrode disconnection member is disposed.

According to an embodiment, the display device may further include a pixel circuit disposed on the base layer. The base electrode may include a same material as any one of electrodes forming the pixel circuit.

According to an embodiment, the base electrode may be disposed between the protruding insulating layer and the base layer. The base electrode may include a conductive material, the protruding insulating layer may include an insulating material, and etching rate of the base electrode and the protruding insulating layer may be different from each other.

According to an embodiment, the display device may further include an outer electrode portion disposed on the protruding insulating layer, and an outer capping portion disposed on the outer electrode portion. At least a portion of the outer electrode portion may be disposed on an inclined side surface of the protruding insulating layer, and the outer capping portion may cover at least a portion of the outer electrode portion disposed on the inclined side surface.

According to an embodiment of the disclosure, a method of manufacturing a display device including a display area and a peripheral area surrounding at least a portion of the display area may be provided. The method may include forming a pixel circuit, and forming a light-emitting-element layer disposed on the pixel circuit and including a light emitting element electrically connected to the pixel circuit. Forming the light-emitting-element layer may include forming a pixel defining layer on a base layer in the display area and a reverse-taper member on the base layer in the peripheral area, forming a light emitting part in an area surrounded by the pixel defining layer in the display area, and forming an electrode layer in the display area and the peripheral area. The reverse-taper member may surround an area and include an inner edge facing the area. The electrode layer may include an electrode portion disposed in the peripheral area. The electrode portion may include a first electrode portion disposed in the area, and a second electrode portion disposed on an upper surface of the reverse-taper member.

According to an embodiment, the forming the light emitting part may include discharging an organic material for forming the light emitting part by using an inkjet printing method.

According to an embodiment, the forming the pixel defining layer and the forming the reverse-taper member may be performed in a same process.

According to an embodiment, the forming the electrode layer depositing may include separating the first electrode portion and the second electrode portion without using a mask.

According to an embodiment, the method may further include removing at least a portion of the second electrode portion disposed on the upper surface of the reverse-taper member.

According to an embodiment of the disclosure, a method of manufacturing a display device including a display area and a peripheral area surrounding at least a portion of the display area may be provided. The method may include forming a pre-etch base electrode on the base layer in the peripheral area, forming a protruding insulating layer on the pre-etch base electrode in the peripheral area, and removing at least a portion of the pre-etch base electrode disposed under the protruding insulating layer.

According to an embodiment, the removing the at least a portion of the pre-etch base electrode may include a wet etching process.

According to an embodiment, the forming the pre-etch base electrode may be performed simultaneously with a forming an electrode in the display area. The forming the protruding insulating layer may be performed simultaneously with a forming an insulating layer in the display area.

According to an embodiment, the method may further include forming a light-emitting-element layer in the display area, the light-emitting-element layer including a first electrode, a second electrode, and a light emitting part disposed between the first electrode and the second electrode, and forming an outer electrode portion in the peripheral area on the protruding insulating layer when forming the second electrode. The pre-etch base electrode may include a first pre-etch base electrode and a second pre-etch base electrode spaced apart from each other with a separation area interposed therebetween. The outer electrode portion may include a first outer electrode portion and a second outer electrode portion physically spaced apart from each other with the protruding insulating layer interposed therebetween.

According to an embodiment, the method may further include forming an outer capping portion on the outer electrode portion, forming an outer encapsulation layer on the outer capping portion, and exposing the outer capping portion by removing the outer encapsulation layer disposed on the outer capping layer.

According to an embodiment of the disclosure, a display device and a method of manufacturing the display device, which may improve device reliability by reducing a moisture permeation risk may be provided.

According to an embodiment of the disclosure, a display device and a method of manufacturing the display device, which may reduce a process cost by simplifying process equipment may be provided.

### BRIEF DESCRIPTION OF THE DRAWINGS

The above and other features of the present disclosure will become more apparent by describing in further detail embodiments thereof with reference to the accompanying drawings, in which:

FIG. 1 is a schematic plan view illustrating a display device according to an embodiment;

FIG. 2 is a schematic cross-sectional view illustrating a display device according to an embodiment;

FIGS. 3 and 4 are schematic cross-sectional views illustrating a pixel-circuit layer and a light-emitting-element layer according to an embodiment;

FIG. 5 is a schematic plan enlarged view illustrating an electrode disconnection area where an electrode disconnection member is disposed according to an embodiment;

FIG. 6 is a schematic enlarged plan view of an EA1 area of FIG. 5 as a view illustrating an electrode disconnection member according to an embodiment;

FIG. 7 is a schematic cross-sectional view taken along the line A˜A′ of FIG. 1 as a view illustrating a display device including the electrode disconnection member according to an embodiment;

FIG. 8 is a schematic cross-sectional view taken along a line B˜B′ of FIG. 6;

FIG. 9 is a schematic enlarged plan view of the EA1 area of FIG. 5 as a view illustrating an electrode disconnection member according to another embodiment;

FIG. 10 is a schematic cross-sectional view taken along the line A˜A′ of FIG. 1 as a view illustrating a display device including the electrode disconnection member according to another embodiment;

FIGS. 11 and 12 are schematic cross-sectional views along a line C˜C′ of FIG. 9;

FIG. 13 is a flowchart illustrating a method of manufacturing a display device according to an embodiment;

FIGS. 14, 15, 16, 17, 18, 19 and 20 are schematic cross-sectional views for each process step illustrating a method of manufacturing a display device according to an embodiment;

FIG. 21 is a flowchart illustrating a method of manufacturing a display device according to another embodiment; and

FIGS. 22, 23, 24 and 25 are schematic cross-sectional views for each process step illustrating a method of manufacturing a display device according to another embodiment.

### DETAILED DESCRIPTION OF THE EMBODIMENT

The present disclosure may be modified in various manners and have various forms. Therefore, specific embodiments will be illustrated in the drawings and will be described in detail in the specification. However, it should be understood that the present disclosure is not intended to be limited to the disclosed specific forms, and the present disclosure includes all modifications, equivalents, and substitutions within the spirit and technical scope of the disclosure.

Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expressions include plural expressions unless the context clearly dictates otherwise.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In addition, a case where a portion of a layer, a layer, an area, a plate, or the like is referred to as being “on” another portion, it includes not only a case where the portion is “directly on” another portion, but also a case where there is further another portion between the portion and the other portion. In addition, in the present specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and the other portion.

The present disclosure relates to a display device and a method of manufacturing the display device. Hereinafter, a display device and a method of manufacturing the display device according to an embodiment are described with reference to the accompanying drawings.

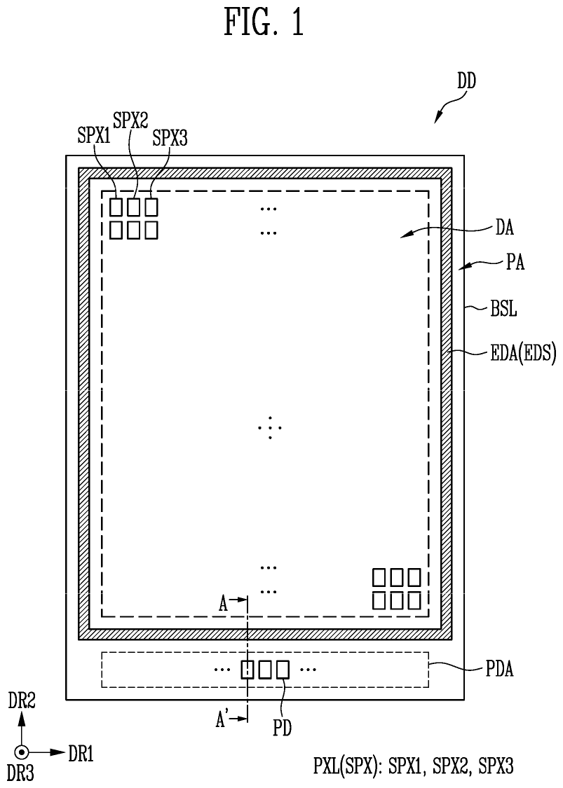

FIG. 1 is a schematic plan view illustrating a display device according to an embodiment.

Referring to FIG. 1, the display device DD may include a base layer BSL and pixels PXL disposed on the base layer BSL. According to an embodiment, the display device DD may further include an electrode disconnection member EDS. The display device DD may further include pads PD.

The display device DD may further include a driving circuit unit (for example, a driving chip including a scan driver and/or a data driver, a circuit board, and the like) and signal lines for driving the pixel PXL.

The display device DD (or the base layer BSL) may include a display area DA and a peripheral area PA. The peripheral area PA may mean an area other than the display area DA. The peripheral area PA may surround at least a portion of the display area DA. The peripheral area PA may include a dead space.

The base layer BSL may form a base surface of the display device DD. The base layer BSL may be a rigid or flexible substrate or film. For example, the base layer BSL may be a rigid substrate formed of glass or tempered glass, a flexible substrate formed of a plastic or metal material, or at least one insulating layer. A material and/or a physical property of the base layer BSL are/is not particularly limited.

The display area DA may mean an area where the pixels PXL are disposed. The peripheral area PA may mean an area where the pixels PXL are not disposed. The driving circuit and the signal lines connected to the pixels PXL in the display area DA may be disposed in the peripheral area PA.

According to an embodiment, the peripheral area PA may include an electrode disconnection area EDA in which the electrode disconnection member EDS is disposed. The peripheral area PA may include a pad area PDA in which the pads PD are disposed.

According to an embodiment, the pixels PXL (or sub-pixels SPX) may be arranged according to a stripe or PENTILE™ arrangement structure, but are not limited thereto, and various embodiments may be applied to the disclosure.

According to an embodiment, the pixels PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one of the first sub-pixel SPX1, the second sub-pixel SPX2, and the third sub-pixel SPX3 may form one pixel unit configured to emit light of various colors.

For example, each of the first sub-pixel SPX1, the second sub-pixel SPX2, and the third sub-pixel SPX3 may emit light of one color. For example, the first sub-pixel SPX1 may be a red pixel emitting light of red (for example, first color), the second sub-pixel SPX2 may be a green pixel emitting light of green (for example, second color), and the third sub-pixel SPX3 may be a blue pixel emitting light of blue (for example, third color). According to an embodiment, the number of second sub-pixels SPX2 may be greater than the number of first sub-pixels SPX1 and the number of third sub-pixels SPX3. However, the color, type, number, and/or the like of the first sub-pixel SPX1, the second sub-pixel SPX2, and the third sub-pixel SPX3 forming each pixel unit are/is not limited to a specific example.

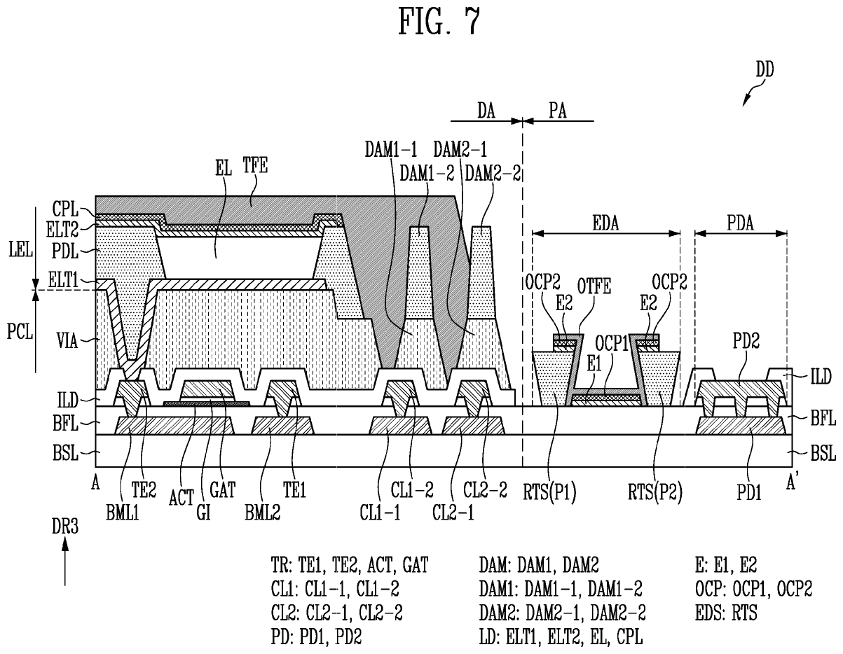

The pads PD may be disposed in the pad area PDA. The pads PD may include conductive layers and may form an electrical connection structure. For example, the pads PD may include a first pad layer PD1 (refer to FIG. 7) and a second pad layer PD2 disposed on the first pad layer PD1 (refer to FIG. 7).

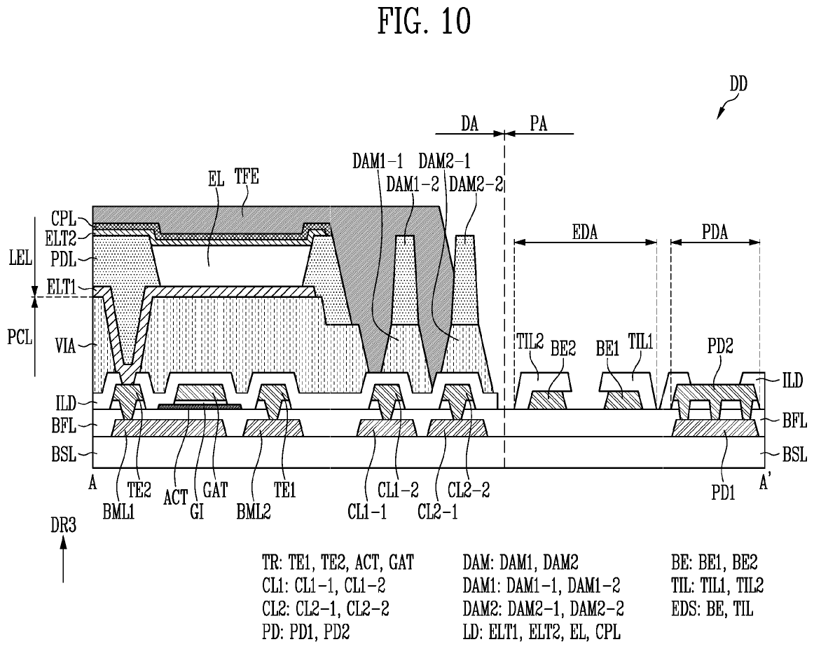

According to an embodiment, each layers of the pads PD may be disposed on a same layer as another conductive layer or other conductive layers in a pixel-circuit layer PCL (for example, a backplane). According to an embodiment, the each layers of the pads PD may be disposed on a same layer as a portion of the electrode disconnection member EDS (for example, a base electrode BE (refer to FIG. 10)).

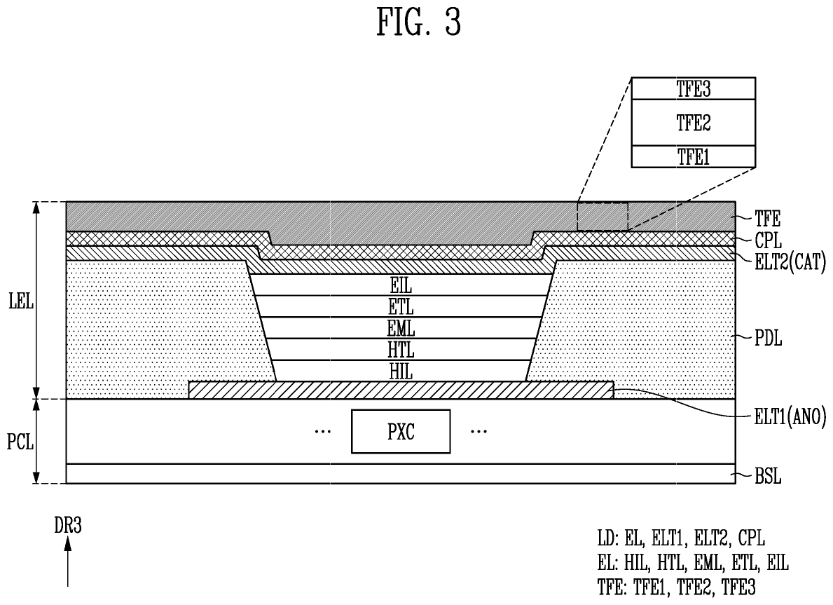

The pad area PDA may be formed on one side of the display area DA. The pads PD may be electrically connected to the driving circuit unit. For example, a circuit board and a driving chip forming the driving circuit unit may be disposed on a rear surface of the base layer BSL, the pads PD may be electrically connected to the circuit board and the driving chip, and the pads PD may be electrically connected to other lines on the base layer BSL. Accordingly, an electrical signal (for example, a driving signal or the like) provided by the driving circuit unit may be provided to a pixel circuit PXC (refer to FIG. 3).

The electrode disconnection member EDS may be disposed in the electrode disconnection area EDA. The electrode disconnection area EDA may be formed around the display area DA. The electrode disconnection area EDA may surround at least a portion of the display area DA. The electrode disconnection area EDA may be formed in a loop shape. The electrode disconnection area EDA may have a closed-loop structure completely surrounding an edge of the display area DA. However, the present disclosure is not limited thereto. The electrode disconnection area EDA may have an open-loop structure. According to an embodiment, at least a portion of the electrode disconnection area EDA may be disposed between the pad area PDA and the display area DA.

The electrode disconnection member EDS may include a structure that may disconnect electrode layers formed (for example, deposited) adjacent to and on the electrode disconnection member EDS from each other. For example, the electrode disconnection member EDS may include a negatively tapered structure. In this case, as a process of forming the electrode layer with disconnected portions is performed without requiring a separate mask (for example, an open mask), the electrode layer deposited in the electrode disconnection area EDA may be disconnected. For example, in the electrode disconnection area EDA, an electrode layer deposited simultaneously with a second electrode ELT2 forming an upper electrode of a light emitting element LD (refer to FIG. 3) may be disconnected.

According to an embodiment, when the electrode layer is disconnected in the peripheral area PA, a risk of permeation of moisture from an outside may be reduced. In addition, disconnection of these electrode layers may be performed without requiring a separate mask (for example, an open mask). Accordingly, a process step may be simplified, a process cost may be reduced, and a moisture permeation issue may be prevented. Related details are described later.

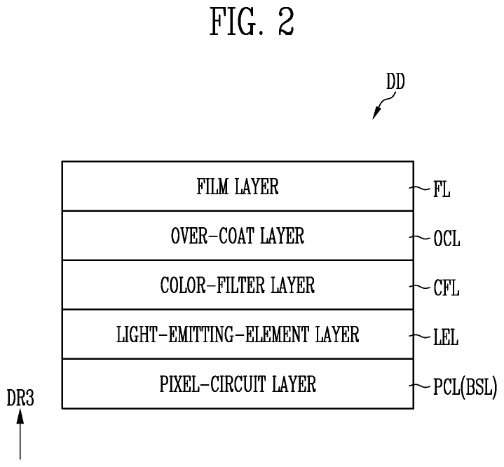

FIG. 2 is a schematic cross-sectional view illustrating a display device according to an embodiment.

Referring to FIG. 2, the display device DD may include a pixel-circuit layer PCL (for example, a backplane layer) and a light-emitting-element layer LEL. According to an embodiment, the display device DD may further include a color filter layer CFL, an overcoat layer OCL, and a functional film layer FL.

The pixel-circuit layer PCL may be a layer including the pixel circuit PXC (refer to FIG. 3) for driving the pixel PXL which includes the light emitting element LD included in the light-emitting-element layer LEL). The pixel-circuit layer PCL may include the base layer BSL, conductive layers for forming pixel circuits, and insulating layers disposed between adjacent conductive layers.

The light-emitting-element layer LEL may be disposed on the pixel-circuit layer PCL. According to an embodiment, the light-emitting-element layer LEL may include the light emitting element LD. According to an embodiment, the light emitting element LD may include an organic light emitting diode (OLED).

The color filter layer CFL may be disposed on the light-emitting-element layer LEL. The color filter layer CFL may include a color filter material (for example, dye or pigment) that selectively transmits light of one color. For example, the color filter layer CFL may include a first color filter included in the first sub-pixel SPX1, a second color filter included in the second sub-pixel SPX2, and a third color filter included in the third sub-pixel SPX3.

The overcoat layer OCL may be disposed on the color filter layer CFL. The overcoat layer OCL may be a planarization layer and may be a protective layer that protects structures disposed under the protective layer from an external influence. The overcoat layer OCL may include an organic material. However, the present disclosure is not limited thereto.

The functional film layer FL may be disposed on the overcoat layer OCL. The functional film layer FL may include one or more of a group of a polyethyleneterephthalate (PET) film, a low reflection film, a polarizing film, and a transmittance controllable film. However, the present disclosure is not limited thereto.

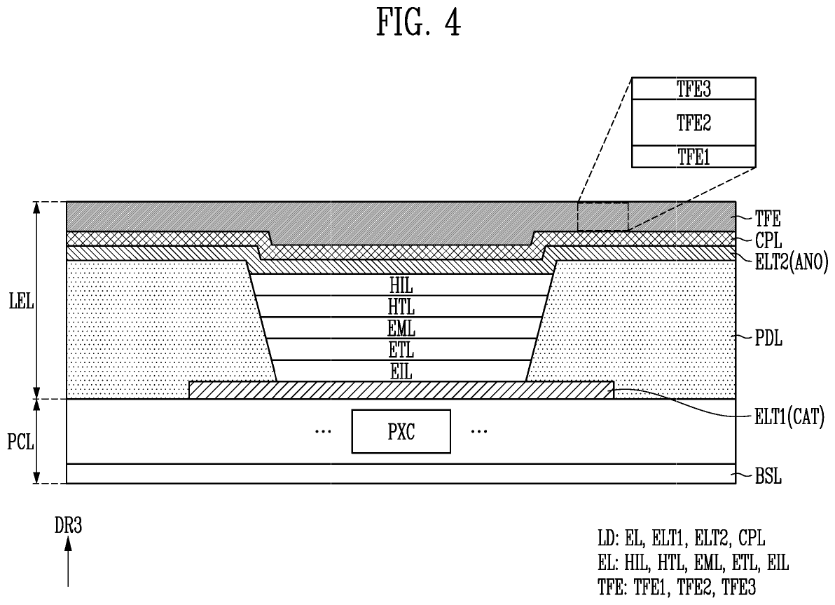

FIGS. 3 and 4 are schematic cross-sectional views illustrating a pixel-circuit layer and a light-emitting-element layer according to an embodiment.

Referring to FIGS. 3 and 4, the pixel-circuit layer PCL may include the pixel circuit PXC disposed (for example, patterned) on the base layer BSL. The pixel circuit PXC may include a driving transistor, a switching transistor, and a storage capacitor, and may further include various other circuit elements. The driving transistor and the switching transistor may be thin film transistors, and may supply an electrical signal to the light emitting element LD to emit light.

According to an embodiment, the light-emitting-element layer LEL may include a pixel defining layer PDL, the light emitting element LD, and an encapsulation layer TFE.

The pixel defining layer PDL may be disposed on the pixel-circuit layer PCL to define a position where the light emitting part EL is disposed. For example, the pixel defining layer PDL may directly adjacent to the light emitting part EL.

According to an embodiment, the pixel defining layer PDL may include a liquid repellent material. Accordingly, the pixel defining layer PDL may suitably accommodate a liquid material discharged into an area (for example, an opening) surrounded by the pixel defining layer PDL. For example, when materials for forming the light emitting part EL are formed through an inkjet printing method, the discharged ink may be prevented from formed on the pixel defining layer PDL.

According to an embodiment, the pixel defining layer PDL may include an organic material. According to an embodiment, the pixel defining layer PDL may include one or more of a group of acrylic resin, epoxy resin, phenol resin, polyamide resin, and polyimide resin. However, the present disclosure is not limited thereto. According to an embodiment, the pixel defining layer PDL may include an inorganic material.

The light emitting element LD may be disposed on the pixel-circuit layer PCL. The light emitting element LD may include a first electrode ELT1, a light emitting part EL, a second electrode ELT2, and a capping layer CPL.

The first electrode ELT1 may be a lower electrode of the light emitting element LD. The second electrode ELT2 may be an upper electrode of the light emitting element LD. For example, the first electrode ELT1 may be disposed between the base layer BSL and the second electrode ELT2.

According to an embodiment, the first electrode ELT1 and the second electrode ELT2 may include a metal layer of a single layer or multiple layers. The first electrode ELT1 and the second electrode ELT2 may include at least one of various metal materials including gold (Au), silver (Ag), aluminum (Al), molybdenum (Mo), chromium (Cr), titanium (Ti), nickel (Ni), neodymium (Nd), copper (Cu), platinum (Pt), and the like, or an alloy thereof. According to an embodiment, the first electrode ELT1 and the second electrode ELT2 may include at least one of various transparent conductive materials including one of a nanowire (AgNW), indium tin oxide (ITO), indium zinc oxide (IZO), indium gallium zinc oxide (IGZO), antimony zinc oxide (AZO), indium tin zinc oxide (ITZO), zinc oxide (ZnO), tin oxide (SnO2), carbon nano tube, and graphene.

The light emitting part EL may be disposed in an area defined by the pixel defining layer PDL. One surface of the light emitting part EL may be electrically connected to the first electrode ELT1, and another surface of the light emitting part EL may be electrically connected to the second electrode ELT2.

The light emitting part EL may include a multi-layer thin film structure and may include typical materials for manufacturing an organic light emitting diode. For example, the light emitting part EL may include a hole injection layer HIL that injects a hole, a hole transport layer HTL having excellent hole transportability and suppressing a movement of an electron that is not combined in a light generation layer to increase a change of recombination of a hole and an electron, a light emitting layer EML including a host and a dopant and emitting light by recombination of the injected electron and hole (for example, formation of an exciton), an electron transport layer ETL for smoothly transporting the electron to the light generation layer, and an electron injection layer EIL that injects the electron. According to an embodiment, the light emitting layer EML may be a quantum dot light emitting layer. However, a material for forming the light emitting part EL is not limited to a specific example.

The light emitting part EL may emit light based on an electrical signal provided from the first electrode ELT1 and the second electrode ELT2.

According to an embodiment (refer to FIG. 3), the first electrode ELT1 may be an anode electrode ANO, and the second electrode ELT2 may be a cathode electrode CAT. Accordingly, the hole injection layer HIL, the hole transport layer HTL, the light emitting layer EML, the electron transport layer ETL, and the electron injection layer EIL may be sequentially disposed on the first electrode ELT1. According to an embodiment, the first electrode ELT1 may be electrically connected to the pixel circuit PXC.

According to an embodiment (refer to FIG. 4), the first electrode ELT1 may be a cathode electrode CAT, and the second electrode ELT2 may be an anode electrode ANO. Accordingly, the electron injection layer EIL, the electron transport layer ETL, the light emitting layer EML, the hole transport layer HTL, and the hole injection layer HIL may be sequentially disposed on the first electrode ELT1. According to an embodiment, the second electrode ELT2 may be electrically connected to the pixel circuit PXC.

According to an embodiment, each of layers forming the light emitting part EL may be formed by various processes. For example, each of the layers forming the light emitting part EL may be formed by a solution process (for example, an inkjet printing method). According to an embodiment, the inkjet printing method may be used to manufacture the light emitting part EL, and thus process efficiency may be improved.

The capping layer CPL may be disposed on the second electrode ELT2. The capping layer CPL may contact the second electrode ELT2. The capping layer CPL may passivate other portions (for example, the second electrode ELT2) of the light emitting element LD.

The capping layer CPL may include an inorganic material. For example, the capping layer CPL may include one or more of a metal or a metal compound. For example, the metal may include one or more of aluminum (Al), silver (Ag), magnesium (Mg), chromium (Cr), titanium (Ti), nickel (Ni), gold (Au), tantalum (Ta), copper (Cu), calcium (Ca), cobalt (Co), iron (Fe), molybdenum (Mo), tungsten (W), platinum (Pt), bismuth (Bi), and ytterbium (Yb). The metal compound may include one or more of a group of silicon oxide (SiOx), titanium oxide (TiOx), zirconium oxide (ZrOx), tantalum oxide (TaxOy), hafnium oxide (HfOx), aluminum oxide (AlxOy), zinc oxide (ZnOx), yttrium oxide (YxOy), beryllium oxide (BeOx), magnesium oxide (MgOx), lead oxide (PbOx), tungsten oxide (WOx), bismuth oxide (BiOx), silicon nitride (SiNx), lithium fluoride (LiFx), calcium fluoride (CaFx), magnesium fluoride (MgFx), and cadmium sulfide (CdSx).

The encapsulation layer TFE may be disposed on the capping layer CPL. The encapsulation layer TFE may planarize a step difference generated by the light emitting element LD, the capping layer CPL, and the pixel defining layer PDL. The encapsulation layer TFE may include a plurality of insulating layers covering the light emitting element LD. According to an embodiment, the encapsulation layer TFE may have a structure in which an inorganic layer and an organic layer are alternately stacked. According to an embodiment, the encapsulation layer TFE may be an encapsulation layer having a structure in which a first inorganic layer TFE1, an organic layer TFE2, and a second inorganic layer TFE3 are sequentially stacked. According to an embodiment, the encapsulation layer TFE may be a thin film encapsulation layer. However, the present disclosure is not limited thereto. According to an embodiment, the encapsulation layer TFE may include a single layer.

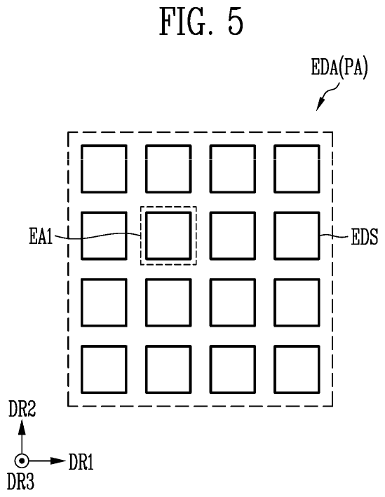

With reference to FIG. 5, a planar structure of the electrode disconnection member EDS is described. FIG. 5 is a schematic plan enlarged view illustrating an electrode disconnection area where an electrode disconnection member is disposed according to an embodiment.

Referring to FIGS. 1 and 5, the electrode disconnection area EDA may be formed in the peripheral area PA.

FIG. 5 schematically illustrates a partial area of the peripheral area PA according to an embodiment. For example, the peripheral area PA may include the electrode disconnection area EDA where the electrode disconnection member EDS is disposed.

According to an embodiment, a plurality of electrode disconnection members EDS may be provided in the electrode disconnection area EDA. For example, the electrode disconnection member EDS may include the plurality of electrode disconnection members EDS spaced apart from each other. According to an embodiment, the electrode disconnection members EDS may be spaced apart in a first direction DR1 or may be spaced apart in a second direction DR2. For example, the electrode disconnection members EDS may be arranged in a matrix structure based on the first direction DR1 and the second direction DR2. However, the present disclosure is not limited thereto.

According to an embodiment, 10 or more electrode disconnection members EDS may be sequentially and repeatedly disposed along the first direction DR1 or the second direction DR2. However, the present disclosure is not limited thereto.

In a plan view, the electrode disconnection members EDS may have sizes equal to each other.

A plane in the present specification may be a direction extending in the first direction DR1 and the second direction DR2 and the base layer BSL may be disposed in the plane.

According to an embodiment, the electrode disconnection members EDS may be disposed on at least one side of the display area DA to reduce a moisture permeation risk to the display device DD. According to an embodiment, since the number of electrode disconnection members EDS along the first direction DR1 and the second direction DR2 is adjusted appropriately, the risk of excessive expansion of the peripheral area PA may be prevented while the moisture permeation risk is suitably prevented.

According to an embodiment, in a plan view, the electrode disconnection members EDS may have a polygonal shape that includes more than three sides. However, the present disclosure is not limited thereto. For example, the electrode disconnection members EDS may have a circular or elliptical shape. The electrode disconnection members EDS may have a rounded corner.

Each of the electrode disconnection members EDS may have a closed-loop structure. For example, in a plan view, the electrode disconnection member EDS may have a shape surrounding edges of one area.

As described above, the electrode disconnection members EDS may have the negatively tapered structure in which the electrodes are disconnected from each other without a separate mask step for disconnecting the electrodes. An electrode enclosed by the electrode disconnection members EDS and an electrode disposed on the electrode disconnection members EDS may be physically separated.

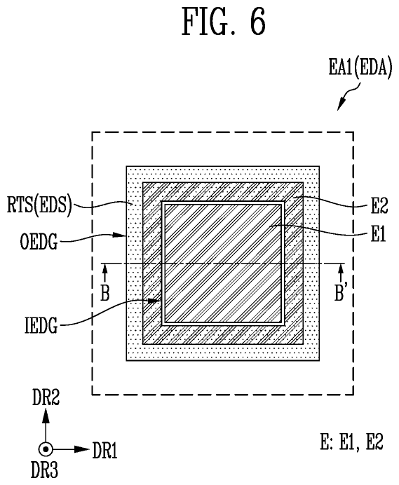

With reference to FIGS. 6 to 8, the electrode disconnection members EDS according to an embodiment are described. For convenience of description, a content that may be repetitive to the above-described content is briefly described or is not repeated.

FIG. 6 is a schematic enlarged plan view of an EA1 area of FIG. 5 as a view illustrating an electrode disconnection member according to an embodiment.

FIG. 7 is a schematic cross-sectional view taken along the line A˜A′ of FIG. 1 as a view illustrating a display device including the electrode disconnection member according to an embodiment FIG. 7 may be a cross-sectional view showing the display area DA and the peripheral area PA together.

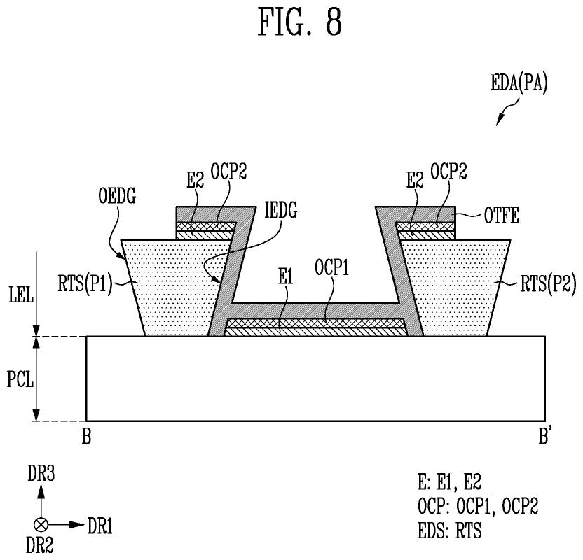

FIG. 8 is a schematic cross-sectional view taken along a line B˜B′ of FIG. 6. FIG. 8 may be a schematic enlarged cross-sectional view illustrating the electrode disconnection member EDS according to an embodiment.

Referring to FIGS. 6 to 8, the electrode disconnection member EDS may include a reverse-taper member RTS. The reverse-taper member RTS may have a closed-loop shape surrounding an area.

The display device DD according to an embodiment may include an electrode portion E. The electrode portion E may be adjacent to the reverse-taper member RTS.

The electrode portion E may include a first electrode portion E1 surrounded by the reverse-taper member RTS and a second electrode portion E2 spaced apart from the first electrode portion E1 and disposed on the reverse-taper member RTS.

The first electrode portion E1 may be disposed in an area surrounded by the reverse-taper member RTS. The first electrode portion E1 may be disposed in an area surrounded by the second electrode portion E2. In a plan view, a shape of the first electrode portion E1 may be decided by a shape of the reverse-taper member RTS.

For example, in a plan view, a shape of edges of the first electrode portion E1 may substantially have the same shape as a shape of inner edges of the reverse-taper member RTS. In a plan view, the edges of the first electrode portion E1 may face the inner edges of the reverse-taper member RTS. For example, the first electrode portion E1 may have a quadrangular shape, and the inner edges of the reverse-taper member RTS may have a same (for example, having a similarity relationship) quadrangular shape as the quadrangular shape of the first electrode portion E1. However, the present disclosure is not limited thereto.

In a plan view, the second electrode portion E2 may be disposed on the reverse-taper member RTS to overlap the reverse-taper member RTS. For example, in a plan view, the second electrode portion E2 may be disposed along the inner edge IEDG of the reverse-taper member RTS on the reverse-taper member RTS. The inner edge IEDG of the reverse-taper member RTS may face a sidewall of the first electrode portion E1 surrounded by the reverse-taper member RTS.

In a plan view, the second electrode portion E2 may not substantially overlap the first electrode portion E1. The second electrode portion E2 may be disposed between an outer edge OEDG of the reverse-taper member RTS and the first electrode portion E1.

A shape of the second electrode portion E2 may correspond to the shape of the reverse-taper member RTS.

For example, in a plan view, a shape of inner edges of the second electrode portion E2 may correspond to (for example, substantially a same as) the shape of the inner edges of the reverse-taper member RTS. In a plan view, outer edges of the second electrode portion E2 may face the inner edges of the reverse-taper member RTS. For example, the second electrode portion E2 may have a quadrangular shape and include an opening surrounded by the second electrode portion E2, and the reverse-taper member RTS may have a same (for example, having a similarity relationship) quadrangular shape as the quadrangular shape of the second electrode portion E2 and include an opening surrounded by the second electrode portion E2. However, the present disclosure is not limited thereto.

The second electrode portion E2 may completely surround the first electrode portion E1.

For example, in a plan view, the shape of the edges of the second electrode portion E2 may be substantially the same as the shape of the edges of the first electrode portion E1. In a plan view, the inner edges of the second electrode portion E2 may face the edges of the first electrode portion E1. For example, the second electrode portion E2 may have a quadrangular shape with an opening, and the first electrode portion E1 may have a quadrangular shape surrounded by the first electrode portion E1 in a plan view. However, the present disclosure is not limited thereto.

Meanwhile, the display device DD according to an embodiment may include conductive layers and insulating layers for forming the pixel-circuit layer PCL.

According to an embodiment, the display device DD may include a first lower auxiliary electrode layer BML1, a second lower auxiliary electrode layer BML2, a buffer layer BFL, a transistor TR, a gate insulating layer GI, an interlayer insulating layer ILD, a first conductive layer CL1, a second conductive layer CL2, a pad PD, a via layer VIA, and a dam DAM.

The first lower auxiliary electrode layer BML1 and the second lower auxiliary electrode layer BML2 may be disposed on the base layer BSL. The first lower auxiliary electrode layer BML1 may be electrically connected to a second transistor electrode TE2. The second lower auxiliary electrode layer BML2 may be electrically connected to a first transistor electrode TE1.

The buffer layer BFL may be disposed on the base layer BSL, and may cover the first lower auxiliary electrode layer BML1, the second lower auxiliary electrode layer BML2, a (1-1)-th conductive layer CL1-1, a (2-1)-th conductive layer CL2-1, and the first pad layer PD1. The buffer layer BFL may prevent diffusion of an impurity or moisture permeation into an active layer ACT. According to an embodiment, the buffer layer BFL may include an inorganic material.

The transistor TR may include the active layer ACT, a gate electrode GAT, the first transistor electrode TE1, and the second transistor electrode TE2.

The active layer ACT may include a semiconductor. For example, the active layer ACT may include one or more of a group of polysilicon, low temperature polycrystalline silicon (LTPS), amorphous silicon, and an oxide semiconductor. According to an embodiment, the active layer ACT may form a channel area.

The gate electrode GAT may overlap the active layer ACT with the gate insulating layer GI interposed therebetween. Each of the first transistor electrode TE1 and the second transistor electrode TE2 may be electrically connected to the active layer ACT. One of the first transistor electrode TE1 and the second transistor electrode TE2 may be a source electrode, and the other may be a drain electrode. According to an embodiment, the gate electrode, the first transistor electrode TE1, and the second transistor electrode TE2 may be disposed on a same layer. However, the present disclosure is not limited thereto.

According to an embodiment, the gate electrode GAT may include various conductive materials and may have a single-layer or multi-layer structure. According to an embodiment, the gate electrode GAT may include at least one of various metal materials including gold (Au), silver (Ag), aluminum (Al), molybdenum (Mo), chromium (Cr), titanium (Ti), nickel (Ni), neodymium (Nd), copper (Cu), platinum (Pt), and the like, or an alloy thereof. For example, the gate electrode GAT may have a structure in which Ti/Al/Ti are sequentially stacked or a structure in which Ti/Cu are sequentially stacked. However, the present disclosure is not limited thereto.

The transistor TR may be a thin film transistor. According to an embodiment, the transistor may include a driving transistor and may further include a switching transistor.

At least a portion of the gate insulating layer GI may be disposed between the gate electrode GAT and the active layer ACT. According to an embodiment, the gate insulating layer GI may be disposed under each of the first transistor electrode TE1, the second transistor electrode TE2, a (1-2)-th conductive layer CL1-2, a (2-2)-th conductive layer CL2-2, and the second pad layer PD2.

The interlayer insulating layer ILD may cover the gate electrode GAT, the first transistor electrode TE1, the second transistor electrode TE2, the (1-2)-th conductive layer CL1-2, the (2-2)-th conductive layer CL2-2, and the second pad layer PD2. The interlayer insulating layer ILD may include an inorganic material. For example, the interlayer insulating layer ILD may include one or more of a group of silicon nitride (SiNx), silicon oxide (SiOx), silicon oxynitride (SiOxNy), and aluminum oxide (AlxOy). However, the present disclosure is not necessarily limited to the above examples.

The first conductive layer CL1 may include the (1-1)-th conductive layer CL1-1 and the (1-2)-th conductive layer CL1-2. The second conductive layer CL2 may include the (2-1)-th conductive layer CL2-1 and the (2-2)-th conductive layer CL2-2. The (1-1)-th conductive layer CL1-1 and the (2-1)-th conductive layer CL2-1 may be disposed on a same layer as the first lower auxiliary electrode layer BML1 and the second lower auxiliary electrode layer BML2. The (1-2)-th conductive layer CL1-2 and the (2-2)-th conductive layer CL2-2 may be disposed on a same layer as the gate electrode GAT.

According to an embodiment, the first conductive layer CL1 and the second conductive layer CL2 may be disposed under the dam DAM to overlap the dam DAM in a plan view to secure a sufficient height of the dam DAM formed on the first conductive layer CL1 and the second conductive layer CL2.

The via layer VIA may be disposed on the interlayer insulating layer ILD. The via layer VIA may be a planarization layer. The via layer VIA may be disposed in the display area DA, and may not be disposed in at least a portion of the peripheral area PA according to an embodiment.

The via layer VIA may include an organic material. For example, the organic material may include one or more of a group of acrylic resin, epoxy resin, phenol resin, polyamide resin, polyimide resin, polyester resin, polyphenylenesulfide resin, and benzocyclobutene (BCB). However, the present disclosure is not necessarily limited to the above-described example.

According to an embodiment, the first electrode ELT1 may be electrically connected to the second transistor electrode TE2 through a contact portion formed through the via layer VIA. Accordingly, the transistor TR may be electrically connected to the light emitting part EL through the first electrode ELT1.

According to an embodiment, the pixel defining layer PDL may expose a portion of the first electrode ELT1 to form an area where the light emitting part EL may be disposed.

According to an embodiment, the dam DAM may be disposed adjacent to the peripheral area PA. The dam DAM may be disposed between an area where the light emitting element LD is disposed and the electrode disconnection area EDA.

The dam DAM may protrude in a thickness direction (for example, a third direction DR3) of the base layer BSL. The dam DAM may include a first dam DAM1 and a second dam DAM2 spaced apart from each other in a plane direction of the base layer BSL. The dam DAM may reduce a risk of overflowing of fluid to the outside when forming the light emitting part EL or the encapsulation layer TFE.

The first dam DAM1 may include a (1-1)-th dam DAM1-1 and a (1-2)-th dam DAM1-2 disposed on the (1-1)-th dam DAM1-1. The second dam DAM2 may include a (2-1)-th dam DAM2-1 and a (2-2)-th dam DAM2-2 disposed on the (2-1)-th dam DAM2-1.

The (1-1)-th dam DAM1-1 and the (2-1)-th dam DAM2-1 may be formed in a same process and may include a same material as the via layer VIA. The (1-2)-th dam DAM1-2 and the (2-2)-th dam DAM2-2 may be formed in a same process and may include a same material as the pixel defining layer PDL. According to an embodiment, the (1-2)-th dam DAM1-2 and the (2-2)-th dam DAM2-2 may be formed in a same process and may include a same material as the reverse-taper member RTS.

According to an embodiment, the second electrode ELT2 and the capping layer CPL may be sequentially disposed on the light emitting part EL, and the encapsulation layer TFE may cover other layers in the display area DA. A portion of the encapsulation layer TFE may be disposed between the first dam DAM1 and the second dam DAM2.

According to an embodiment, the electrode disconnection area EDA where the electrode disconnection member EDS is disposed may be disposed adjacent to an edge of the display area DA.

According to an embodiment, the electrode disconnection member EDS may be disposed between the display area DA and the pad area PDA. The electrode disconnection member EDS may be disposed adjacent to the pad PD. For example, the reverse-taper member RTS forming the electrode disconnection member EDS may include a first portion P1 and a second portion P2. The first portion P1 may face the display area DA, and the second portion P2 may face the pad area PDA.

According to an embodiment, an outer capping layer OCP may be disposed on the electrode portion E disposed adjacent to the reverse-taper member RTS.

The outer capping layer OCP may cover the electrode portion E. The outer capping layer OCP may include a first outer capping layer OCP1 disposed on the first electrode portion E1 and a second outer capping layer OCP2 disposed on the second electrode portion E2.

According to an embodiment, an outer encapsulation layer OTFE may be disposed on the outer capping layer OCP.

The outer encapsulation layer OTFE may cover the outer capping layer OCP. For example, the outer encapsulation layer OTFE may cover the first outer capping layer OCP1 and the second outer capping layer OCP2, and may further cover an inner surface of the reverse-taper member RTS.

According to an embodiment, the electrode disconnection member EDS may be formed in at least partially same process as other layers of the light-emitting-element layer LEL disposed in the display area DA.

For example, the reverse-taper member RTS may be formed in a same process as the pixel defining layer PDL disposed in the light-emitting-element layer LEL. The reverse-taper member RTS and the pixel defining layer PDL may include a same material. The reverse-taper member RTS and the pixel defining layer PDL may include a material of a same composition. The reverse-taper member RTS and the pixel defining layer PDL may be disposed on a same layer.

For example, the electrode portion E may be formed in a same process as the second electrode ELT2 disposed in the light-emitting-element layer LEL. The electrode portion E and the second electrode ELT2 may include a same material. The electrode portion E and the second electrode ELT2 may include a material of a same composition. The electrode portion E and the second electrode ELT2 may be disposed on a same layer.

For example, the outer capping layer OCP may be formed in a same process as the capping layer CPL disposed in the light-emitting-element layer LEL. The outer capping layer OCP and the capping layer CPL may include a same material. The outer capping layer OCP and the capping layer CPL may include a material of a same composition. The outer capping layer OCP and the capping layer CPL may be disposed on a same layer.

For example, the outer encapsulation layer OTFE may be formed in a same process as the encapsulation layer TFE disposed in the light-emitting-element layer LEL. The outer encapsulation layer OTFE and the encapsulation layer TFE may include a same material. The outer encapsulation layer OTFE and the encapsulation layer TFE may include a material of a same composition. The outer encapsulation layer OTFE and the encapsulation layer TFE may be disposed on a same layer.

According to an embodiment, the first outer capping layer OCP1 may cover an upper surface of the first electrode portion E1. The second outer capping layer OCP2 may cover an upper surface of the second electrode portion E2. The outer encapsulation layer OTFE may cover an upper surface of the first outer capping layer OCP1 and the second outer capping layer OCP2. The outer encapsulation layer OTFE may cover a side surface of each of the first outer capping layer OCP1, the second outer capping layer OCP2, the first electrode portion E1, and the second electrode portion E2.

According to an embodiment, the outer encapsulation layer OTFE may cover one side surface (for example, the inner edge IEDG) of the reverse-taper member RTS, and the outer encapsulation layer OTFE may expose another side surface (for example, the outer edge OEDG) of the reverse-taper member RTS.

According to an embodiment, at least a portion of an upper surface of the reverse-taper member RTS may be exposed. According to an embodiment, the second electrode portion E2, the second outer capping layer OCP2, and the outer encapsulation layer OTFE may partially cover the upper surface of the reverse-taper member RTS disposed adjacent to the first electrode portion E1. According to an embodiment, each side portion of the second electrode portion E2, the second outer capping layer OCP2, and the outer encapsulation layer OTFE disposed on the upper surface of the reverse-taper member RTS may be exposed. According to an embodiment, the second electrode portion E2 may cover an edge of the upper surface of the reverse-taper member RTS disposed adjacent to the inner edge IEDG.

According to an embodiment, the second electrode portion E2, the second outer capping layer OCP2, and the outer encapsulation layer OTFE may be patterned in a same etching process. For example, after sequentially depositing layers for forming each of the second electrode portion E2, the second outer capping layer OCP2, and the outer encapsulation layer OTFE, the respective layers may be collectively (for example, simultaneously) etched (for example, dry etched) using the same mask. In this case, the second electrode portion E2 may have an island structure that is not electrically connected to another conductive structure. Accordingly, a risk of moisture penetrating into the display area DA may be more thoroughly prevented.

According to an embodiment, the first electrode portion E1 and the second electrode portion E2 may be spaced apart from each other. For example, each of the first electrode portion E1 and the second electrode portion E2 may include edges (for example, ends) that face each other in a plan view.

According to an embodiment, the first outer capping layer OCP1 and the second outer capping layer OCP2 may be spaced apart from each other. For example, each of the first outer capping layer OCP1 and the second outer capping layer OCP2 may include edges (for example, ends) that face each other in a plan view.

Experimentally, when a conductive path is formed in the peripheral area PA, the moisture permeation issue in which moisture penetrates into the display device DD may occur through the conductive path.

According to an embodiment, the conductive path may be disconnected by forming the electrode disconnection member EDS, and thus the moisture permeation issue may be substantially prevented. For example, since the first electrode portion E1 and the second electrode portion E2 are spaced apart from each other, and the first outer capping layer OCP1 and the second outer capping layer OCP2 are spaced apart from each other, the moisture permeation risk is may be reduced.

Experimentally, when the second electrode ELT2 is deposited without a mask, a conductive path may be formed in at least a partial area of the display device DD, and thus the moisture permeation risk may occur. Alternatively, when the second electrode ELT2 is patterned using a mask (for example, an open mask), the number of masks may increase, and thus a process cost may be increased.

However, according to an embodiment, when the electrode disconnection member EDS is formed and a conductive layer for forming the second electrode ELT2 is deposited on the electrode disconnection member EDS, the first electrode portion E1 and the second electrode portion E2 may be disconnected due to the reverse taper member without using a separate mask. Accordingly, since a disconnection structure may be formed without requiring a mask for patterning the first electrode portion E1 and the second electrode portion E2, a process cost may be reduced.

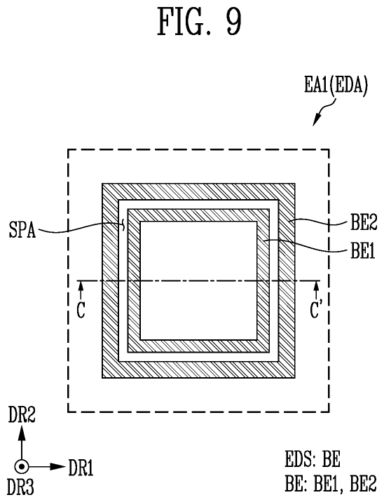

With reference to FIGS. 9 to 12, electrode disconnection members EDS according to another embodiment are described. For convenience of description, a content that may be repetitive to the above-described content is briefly described or is not repeated.

FIG. 9 is a schematic enlarged plan view of the EA1 area of FIG. 5 as a view illustrating the electrode disconnection member according to another embodiment.

FIG. 10 is a schematic cross-sectional view taken along the line A˜A′ of FIG. 1 as a view illustrating a display device including the electrode disconnection member according to another embodiment. FIG. 10 may be a cross-sectional view showing the display area DA and the peripheral area PA together.

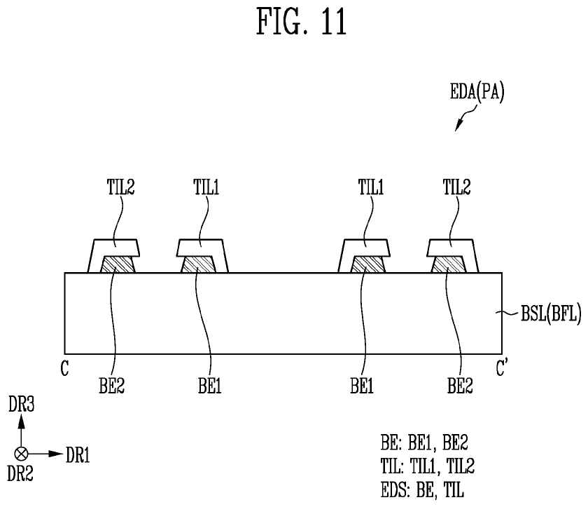

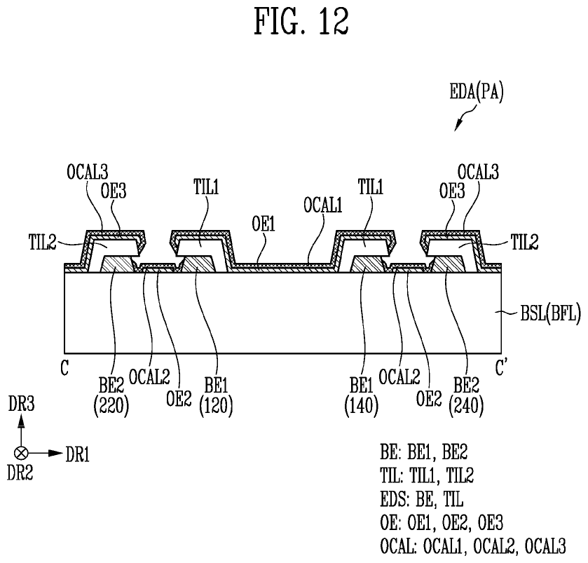

FIGS. 11 and 12 are schematic cross-sectional views along a line C˜C′ of FIG. 9. FIGS. 11 and 12 may be schematic enlarged cross-sectional views illustrating the electrode disconnection member EDS according to another embodiment.

The display device DD according to the present embodiment is different from the display device DD according to the previous embodiment, in that the electrode disconnection member EDS includes a base electrode BE and a protruding insulating layer TIL.

According to an embodiment, the base electrode BE may have a shape (for example, a closed-loop shape) surrounding an area.

The base electrode BE may include a first base electrode BE1 and a second base electrode BE2 spaced apart from each other.

The first base electrode BE1 may be disposed in an area surrounded by the second base electrode BE2. Shapes of the first base electrode BE1 and the second base electrode BE2 may be substantially a same.

The first base electrode BE1 and the second base electrode BE2 may face each other with a separation area SPA interposed therebetween. The first base electrode BE1 and the second base electrode BE2 may not overlap each other in a plan view.

According to an embodiment, the first base electrode BE1 may have an internal closed-loop structure in the electrode disconnection member EDS. The second base electrode BE2 may have an external closed-loop structure in the electrode disconnection member EDS. Accordingly, in a plan view, the separation area SPA may be entirely surrounded by the base electrodes BE.

According to an embodiment, the first base electrode BE1 and the second base electrode BE2 may be disposed on the base layer BSL. For example, the first base electrode BE1 and the second base electrode BE2 may be disposed on the buffer layer BFL.

According to an embodiment, the first base electrode BE1 and the second base electrode BE2 may be electrodes disposed in the pixel-circuit layer PCL, and may be formed in a same process as any one of electrodes for forming the pixel circuit PXC. For example, the first base electrode BE1 and the second base electrode BE2 may be formed in a same process as the gate electrode GAT (or the first and second transistor electrodes TE1 and TE2) disposed in the pixel-circuit layer PCL. The base electrodes BE and the gate electrode GAT (or the first and second transistor electrodes TE1 and TE2) may include a same material. The base electrodes BE and the gate electrode GAT (or the first and second transistor electrodes TE1 and TE2) may include a material of a same composition. The base electrodes BE and the gate electrode GAT (or the first and second transistor electrodes TE1 and TE2) may be disposed on a same layer.

For example, the base electrode BE may include various conductive materials and may have a single-layer or multi-layer structure. According to an embodiment, the base electrode BE may include at least one of various metal materials including gold (Au), silver (Ag), aluminum (Al), molybdenum (Mo), chromium (Cr), titanium (Ti), nickel (Ni), neodymium (Nd), copper (Cu), platinum (Pt), and the like, or an alloy thereof. For example, the base electrode BE may have a structure in which Ti/Al/Ti are sequentially stacked or a structure in which Ti/Cu are sequentially stacked. However, the present disclosure is not limited thereto.

The protruding insulating layer TIL may be disposed on the base electrode BE. The protruding insulating layer TIL may have a structure protruding from an upper surface of the base electrode BE. For example, the protruding insulating layer TIL may have a tip-portion protruding an edge of the base electrode BE. That is, the base electrode BE may have an undercut portion disposed under the tip portion of the protruding insulating layer TIL.

The protruding insulating layer TIL may entirely cover the upper surface of the base electrode BE. The protruding insulating layer TIL may cover one side surface of the base electrode BE and may expose another side surface of the base electrode BE. For example, at least a portion of a lower surface of the protruding insulating layer TIL may not contact the base electrode BE in the undercut portion.

According to an embodiment, the protruding insulating layer TIL may be formed in a same process as the interlayer insulating layer ILD disposed in the pixel-circuit layer PCL. The protruding insulating layer TIL and the interlayer insulating layer ILD may include a same material. The protruding insulating layer TIL and the interlayer insulating layer ILD may include a material of a same composition. The protruding insulating layer TIL and the interlayer insulating layer ILD may be disposed on a same layer.

However, the present disclosure is not limited thereto. For example, the protruding insulating layer IL may be formed in a same process as the via layer VIA. Hereinafter, for convenience of description, the present disclosure is described based on an embodiment in which the protruding insulating layer TIL and the interlayer insulating layer ILD are formed in a same process.

According to an embodiment, the separation area SPA may be defined between the first base electrode BE1 and the second base electrode BE2, and thus electrodes that may cause the moisture permeation issue may be spaced apart. In particular, since the separation area SPA may form a closed-loop structure, the electrodes may be more thoroughly spaced apart.

Meanwhile, an outer electrode portion OE and an outer capping portion OCAL may be disposed adjacent to the electrode disconnection member EDS including the protruding insulating layer TIL and the base electrode BE.

The outer electrode portion OE may be formed in a same process as the second electrode ELT2 disposed in the light-emitting-element layer LEL. The outer electrode portion OE and the second electrode ELT2 may include a same material. The outer electrode portion OE and the second electrode ELT2 may include a material of a same composition. The outer electrode portion OE and the second electrode ELT2 may be disposed on a same layer.

The outer electrode portion OE may include a first outer electrode portion OE1, a second outer electrode portion OE2, and a third outer electrode portion OE3 spaced apart from each other.

According to an embodiment, the first outer electrode portion OE1 may be disposed between the first base electrodes BE1. For example, the first base electrodes BE1 may include a (1-1)-th base portion 120 and a (1-2)-th base portion 140, a portion of the first outer electrode portion OE1 may be disposed between the (1-1)-th base portion 120 and the (1-2)-th base portion 140, and another portion of the first outer electrode portion OE1 may be disposed on each of the (1-1)-th base portion 120 and the (1-2)-th base portion 140. Another portion of the first outer electrode portion OE1 may be disposed on a first protruding insulating layer TIL1. Another portion of the first outer electrode portion OE1 may cover a side surface of the first protruding insulating layer TIL1.

According to an embodiment, the second outer electrode portion OE2 may be disposed between the first base electrode BE1 and the second base electrode BE2. For example, the second base electrode BE2 may include a (2-1)-th base portion 220 and a (2-2)-th base portion 240, a portion of the second outer electrode portion OE2 may be disposed between the (1-1)-th base portion 120 and the (2-1)-th base portion 220, and another portion of the second outer electrode portion OE2 may be disposed between the (1-2)-th base portion 140 and the (2-2)-th base portion 240. According to an embodiment, the second outer electrode portion OE2 may be disposed between the first protruding insulating layer TIL1 and a second protruding insulating layer TIL2 in a plan view.

According to an embodiment, the third outer electrode portion OE3 may be disposed on the second base electrode BE2. The third outer electrode portion OE3 may be disposed on the second protruding insulating layer TIL2. A portion of the third outer electrode portion OE3 may be disposed outside the second protruding insulating layer TIL2.

The outer capping portion OCAL may be formed in a same process as the capping layer CPL disposed in the light-emitting-element layer LEL. The outer capping portion OCAL and the capping layer CPL may include a same material. The outer capping portion OCAL and the capping layer CPL may include a material of a same composition. The outer capping portion OCAL and the capping layer CPL may be disposed on a same layer.

The outer capping portion OCAL may include a first outer capping portion OCAL1, a second outer capping portion OCAL2, and a third outer capping portion OCAL3.

According to an embodiment, the first outer capping portion OCAL1 may be disposed on the first outer electrode portion OE1. The first outer capping portion OCAL1 may entirely cover an upper surface of the first outer electrode portion OE1. According to an embodiment, the first outer capping portion OCAL1 may entirely cover the first outer electrode portion OE1 disposed on an inclined side surface of the first protruding insulating layer TIL1.

According to an embodiment, the second outer capping portion OCAL2 may be disposed on the second outer electrode portion OE2. The second outer capping portion OCAL2 may entirely cover an upper surface of the second outer electrode portion OE2. According to an embodiment, the second outer capping portion OCAL2 may entirely cover the second outer electrode portion OE2 disposed on an inclined side surface of the second protruding insulating layer TIL2.

According to an embodiment, the third outer capping portion OCAL3 may be disposed on the third outer electrode portion OE3. The third outer capping portion OCAL3 may entirely cover an upper surface of the third outer electrode portion OE3. According to an embodiment, a portion of the third outer capping portion OCAL3 may contact side surfaces of each of the exposed first base electrode BE1 and second base electrode BE2.

According to an embodiment, the outer capping portion OCAL may entirely cover an upper surface of the outer electrode portion OE, and thus the moisture permeation issue may be more thoroughly prevented.

According to an embodiment, similar to the previous embodiment, even in a case where a deposition process for forming the second electrode ELT2 is performed without a mask, the electrode disconnection member EDS including the base electrode BE and the protruding insulating layer TIL may be formed, and thus a conductive layer for forming the second electrode ELT2 may be disconnected in the peripheral area PA. Accordingly, the moisture permeation risk may be prevented while a less mask is realized.

Meanwhile, according to an embodiment, a layer formed in a same process as the encapsulation layer TFE may not be disposed in the electrode disconnection area EDA.

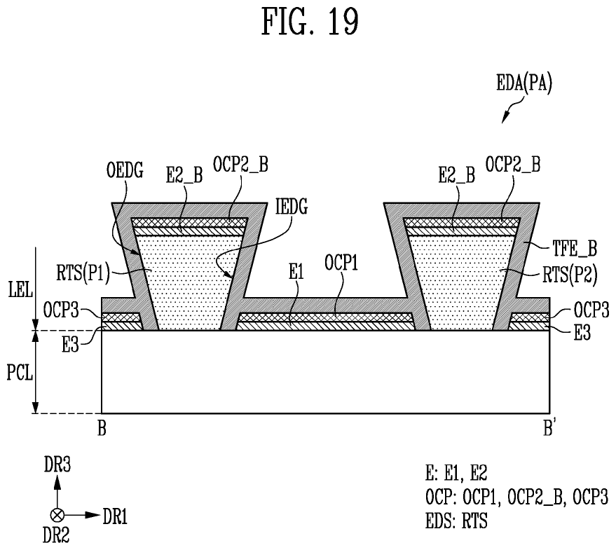

For example, after a base encapsulation layer TFE_B (refer to FIG. 19) forming the encapsulation layer TFE is formed in the display area DA and the electrode disconnection area EDA, when etching process (for example, dry etching) for patterning the encapsulation layer TFE is performed, a portion of the base encapsulation layer TFE_B formed in the electrode disconnection area EDA may be removed.

Accordingly, a portion of the base encapsulation layer TFE_B may be used as a sacrificial layer, and the outer capping portion OCAL may be exposed in the electrode disconnection area EDA. According to an embodiment, in order for the base encapsulation layer TFE_B to be used as the sacrificial layer, a thickness of the base encapsulation layer TFE_B may be 150000 Å or more. However, the present disclosure is not limited thereto.

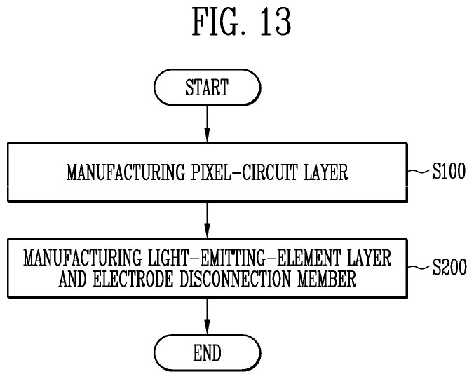

With reference to FIGS. 13 to 20, a method of manufacturing a display device DD including the electrode disconnection members EDS according to an embodiment is described. For convenience of description, a contents that may be repetitive to the above-described content is briefly described or is not repeated.

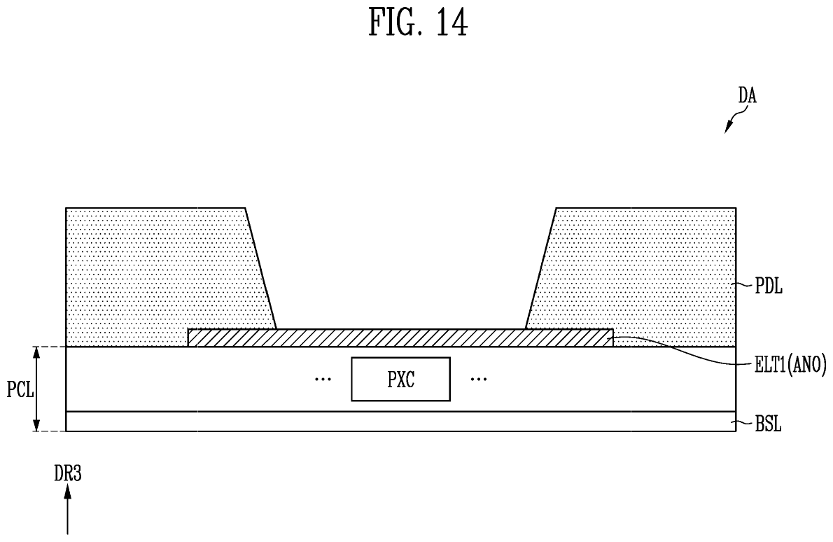

FIGS. 14 to 16 show the light-emitting-element layer LEL described above with reference to FIG. 3.

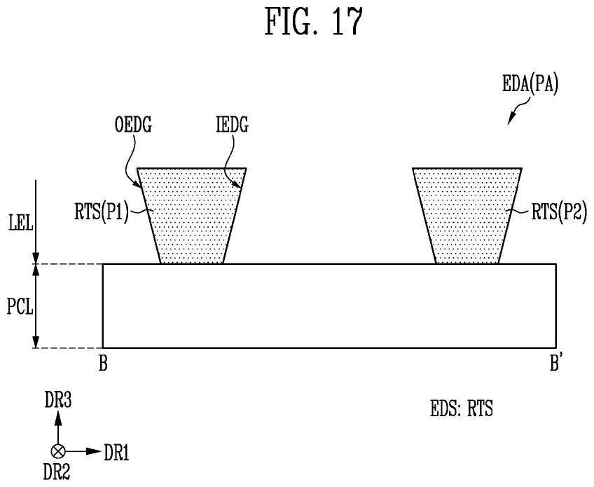

FIGS. 17 to 20 show the display device DD including the electrode disconnection member EDS according to the embodiment described above with reference to FIGS. 6 to 8.

FIG. 13 is a flowchart illustrating a method of manufacturing a display device according to an embodiment.

FIGS. 14 to 20 are schematic cross-sectional views for each process step illustrating a method of manufacturing a display device according to an embodiment. FIGS. 14 to 16 may be schematic cross-sectional views for each process step illustrating a method of manufacturing the light emitting element LD according to an embodiment. FIGS. 17 to 20 may be schematic cross-sectional views for each process step illustrating a method of manufacturing the electrode disconnection member EDS according to an embodiment.

Referring to FIG. 13, a method of manufacturing the display device DD according to an embodiment may include manufacturing the pixel-circuit layer (S100) and manufacturing the light-emitting-element layer and the electrode disconnection member (S200).

Referring to FIGS. 13, 14, and 17, in manufacturing the pixel-circuit layer (S100), the pixel-circuit layer PCL may be formed on the base layer BSL.

In manufacturing the pixel-circuit layer (S100), the pixel circuit PXC may be formed on the base layer BSL. A conductive layers or an insulating layers may be formed on the base layer BSL using a typical processes for manufacturing a semiconductor device. For example, the conductive layers or the insulating layers may be formed by photolithography processes after forming a conductive material layers and an insulating material layers on the base layer BSL by various methods (sputtering, chemical vapor deposition, and the like). The present disclosure is not necessarily limited to a particular example.

Referring to FIGS. 13 and 14 to 20, in manufacturing the light-emitting-element layer and the electrode disconnection member (S200), the electrode disconnection member EDS may be formed in the electrode disconnection area EDA, and the light emitting element LD may be formed in the display area DA.

Referring to FIGS. 14 and 17, the first electrode ELT1 and the pixel defining layer PDL may be formed in the pixel-circuit layer PCL in the display area DA, and the reverse-taper member RTS may be formed in the peripheral area PA in the electrode disconnection area EDA.

Referring to FIG. 14, the first electrode ELT1 for forming the anode electrode ANO may be formed on the pixel-circuit layer PCL in the display area DA, and the pixel defining layer PDL may be patterned so that at least a portion of the first electrode ELT1 is exposed.

Referring to FIG. 17, a layer (for example, a liquid repellent material layer) for manufacturing the reverse-taper member RTS may be formed (for example, deposited) in the electrode disconnection area EDA, and the reverse-taper member RTS may be formed by further etching a lower portion of the formed layer.

Referring to FIG. 6, which is described above, the reverse-taper member RTS may be patterned to have a closed-loop shape to surround one area. Accordingly, the reverse-taper member RTS may be provided to include a first portion P1 and a second portion P2.

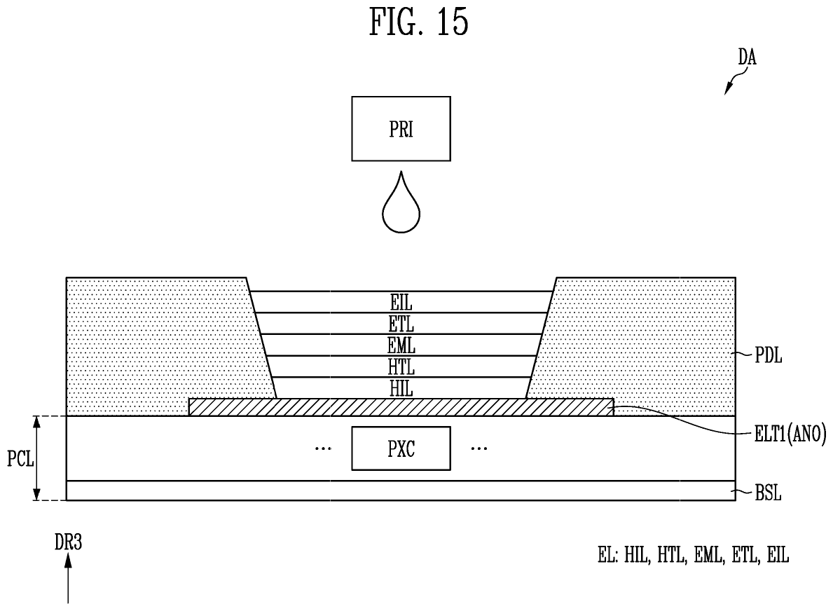

Referring to FIG. 15, a solution process for manufacturing the light emitting part EL in the display area DA may be performed. For example, an inkjet printer PRI including an ink nozzle may discharge an ink including an organic material for forming the light emitting part EL. The discharged ink may be supplied to an area surrounded by the pixel defining layer PDL, and layers forming the light emitting part EL may be sequentially formed.

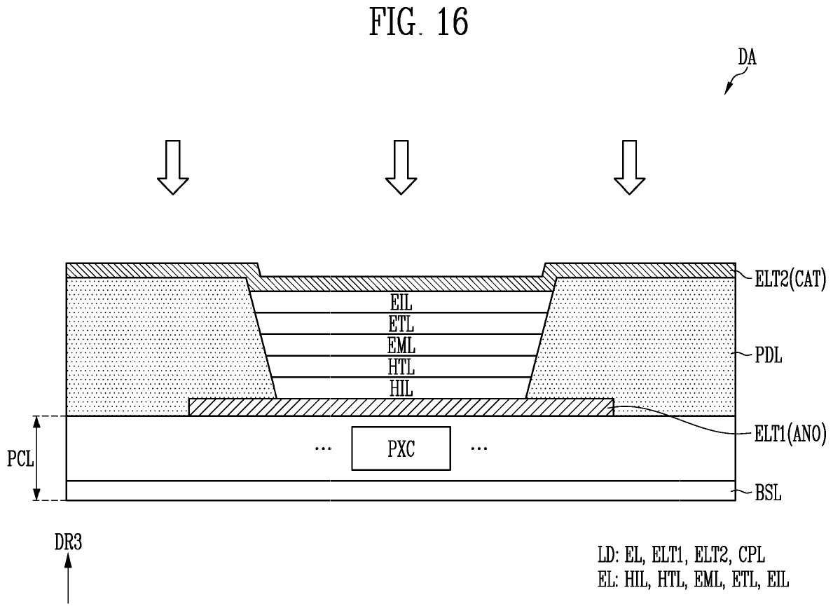

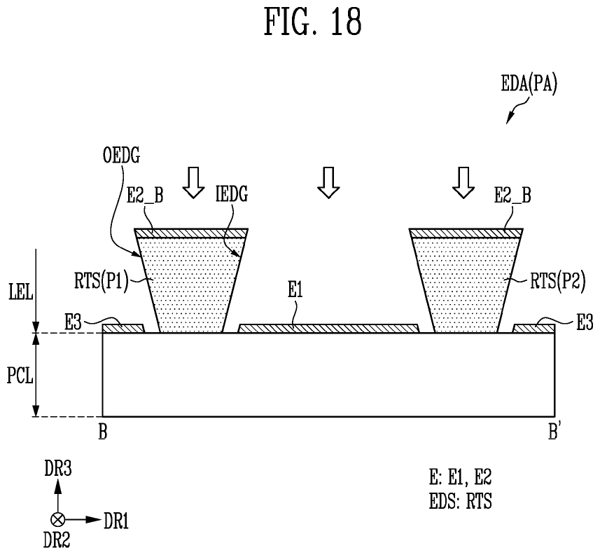

According to an embodiment, since an inkjet printing method may be used to form the light emitting portion EL, the number of masks may not be further required. Referring to FIGS. 16 and 18, the second electrode ELT2 may be formed in the display area DA, and the electrode portion E may be formed in the electrode disconnection area EDA.

According to an embodiment, the second electrode ELT2 and the electrode portion E may be formed through a deposition process without a mask. For example, the second electrode ELT2 and the electrode portion E may be formed by depositing an electrode layer in the display area DA and the peripheral area PA without a mask.

In the present step, the second electrode ELT2 deposited in the display area DA may form an upper electrode of the light emitting element LD, and may contact an upper surface of the light emitting part EL.

In the present step, a portion of the electrode portion E deposited in the electrode disconnection area EDA may be formed between the first portion P1 and the second portion P2 of the reverse-taper member RTS to form the first electrode portion E1. Another portion of the electrode portion E deposited in the electrode disconnection area EDA may be formed on the upper surface of the reverse-taper member RTS to form a second pre-etch electrode portion E2_B. Still another portion of the electrode portion E deposited in the electrode disconnection area EDA may be formed outside the reverse-taper member RTS to form a third electrode portion E3.

According to an embodiment, due to a cross-sectional shape of the reverse-taper member RTS, when the electrode portion E is deposited, the second pre-etch electrode portion E2_B may be physically separated from the first electrode portion E1 and the third electrode portion E3. As described above, since each of portions of the electrode portions E does not physically contact each other, a moisture permeation prevention structure may be formed.

Referring to FIG. 19, the outer capping layer OCP and the base encapsulation layer TFE_B may be formed.

According to an embodiment, the outer capping layer OCP and the base encapsulation layer TFE_B may be formed in the electrode disconnection area EDA to cover the electrode portion E and the reverse-taper member RTS.

Meanwhile, the outer capping layer OCP may be formed in a same process as the capping layer CPL in the display area DA. The base encapsulation layer TFE_B may be formed in a same process as the encapsulation layer TFE in the display area DA.

According to an embodiment, a portion of the outer capping layer OCP may be formed on the first electrode portion E1 to form the first outer capping layer OCP1. Another portion of the outer capping layer OCP may be formed on the reverse-taper member RTS to form a second pre-etch outer capping layer OCP2_B. Still another portion of the outer capping layer OCP may be formed outside the reverse-taper member RTS to form a third outer capping layer OCP3.

In the present step, the base encapsulation layer TFE_B may cover the first to third outer capping layers OCP1, OCP2, and OCP3 and may cover a side surface of the reverse-taper member RTS.

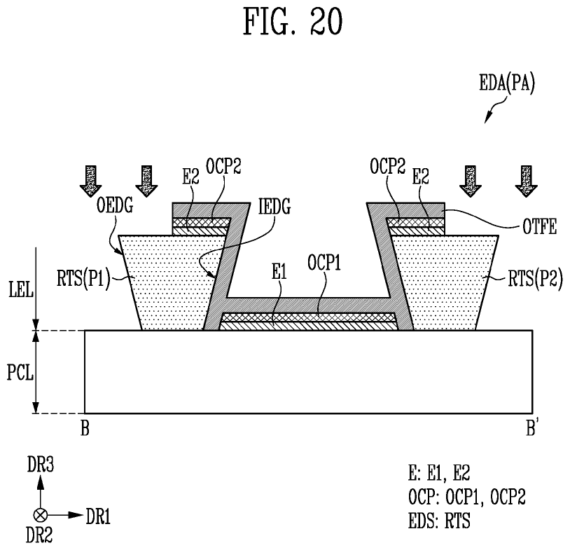

Referring to FIG. 20, at least a portion of each of the base encapsulation layer TFE_B, the outer capping layer OCP, and the electrode portion E may be etched (for example, dry etched).

For example, in the electrode disconnection area EDA, the base encapsulation layer TFE_B, the outer capping layer OCP, and the electrode portion E disposed outside the reverse-taper member RTS may be removed. In addition, in the electrode disconnection area EDA, at least a portion of each of the base encapsulation layer TFE_B, the outer capping layer OCP, and the electrode portion E disposed on the upper surface of the reverse-taper member RTS may be removed.

Meanwhile, in the present step, the base encapsulation layer TFE_B formed in the display area DA may not be etched and may be provided as the encapsulation layer TFE covering the light emitting element LD.

Thereafter, additional layers may be disposed on the light-emitting-element layer LEL, and the display device DD according to an embodiment described above with reference to FIGS. 6 to 8 may be manufactured.

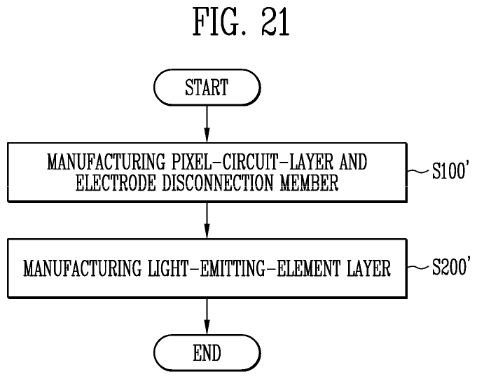

With reference to FIGS. 21 to 25 together with FIGS. 14 to 16, a method of manufacturing the display device DD including the electrode disconnection members EDS according to another embodiment is described. For convenience of description, a content that may be repetitive to the above-described content is briefly described or is not repeated.

FIGS. 21 to 25 show the display device DD including the electrode disconnection member EDS according to the embodiment described above with reference to FIGS. 9 to 12.

FIG. 21 is a flowchart illustrating a method of manufacturing a display device according to another embodiment.

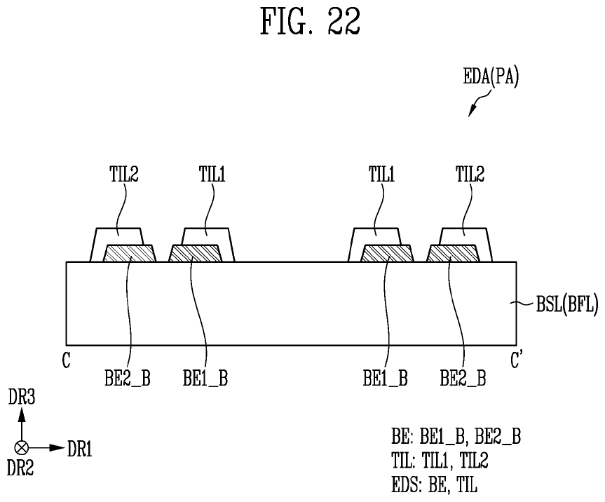

FIGS. 22 to 25 are schematic cross-sectional views for each process step illustrating a method of manufacturing a display device according to another embodiment. FIGS. 22 to 25 may be schematic cross-sectional views for each process step illustrating a method of manufacturing the electrode disconnection member EDS according to another embodiment.

A method of manufacturing the display device DD according to another embodiment may include manufacturing the pixel-circuit layer and the electrode disconnection member (S100′) and manufacturing the light-emitting-element layer S200′.

Manufacturing the pixel-circuit layer and the electrode disconnection member (S100′) is different from manufacturing the pixel-circuit layer (S100) described above, in that forming the electrode disconnection member EDS is further performed.

For example, referring to FIGS. 22 to 25, when the pixel-circuit layer PCL is formed by patterning a conductive layer and an insulating layer, the electrode disconnection member EDS may be formed.

Referring to FIG. 22, in the present step, a pre-etch base electrode BE may be patterned on the base layer BSL (for example, the buffer layer BFL). According to an embodiment, the pre-etch base electrode BE may be formed in a same process as the gate electrode GAT. In addition, the protruding insulating layer TIL may be formed on the pre-etch base electrode BE. According to an embodiment, at least a portion of an upper surface of the pre-etch base electrode BE_B may be exposed by the protruding insulating layer TIL. For example, in a plan view, a portion of the pre-etch base electrode BE may protrude from the protruding insulating layer TIL.

According to an embodiment, the pre-etch base electrode BE may include a first pre-etch base electrode BE1_B for manufacturing the first base electrode BE1 and a second pre-etch base electrode BE2_B for manufacturing the second base electrode BE2. The first protruding insulating layer TIL1 may cover a portion of an upper surface of the pre-etch first base electrode BE1_B, and the second protruding insulating layer TIL2 may cover an upper surface of the second pre-etch base electrode BE2_B.

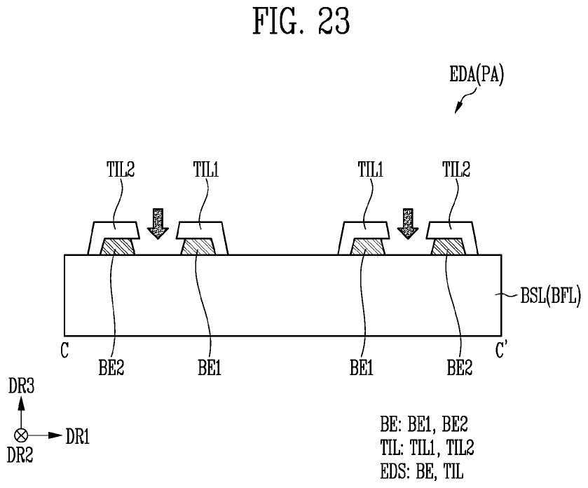

Referring to FIG. 23, at least a portion of the pre-etch base electrode BE may be etched.

According to an embodiment, the pre-etch base electrode BE may be etched by a wet etching process. According to an embodiment, due to a difference in an etch rate between the pre-etch base electrode BE and the protruding insulating layer TIL, only the pre-etch base electrode BE may be substantially etched. Accordingly, after the present etching process is performed, the protruding insulating layer TIL may be provided to protrude from the base electrode BE in one direction.

In the present step, a portion of the first pre-etch base electrode BE1_B may be etched. Therefore, a portion of a lower surface of the first protruding insulating layer TIL1 may be exposed, and the first base electrode BE1 may be provided. The first protruding insulating layer TIL1 may protrude in one direction with respect to the first base electrode BE1.

In the present step, a portion of the second pre-etch base electrode BE2_B may be etched. Therefore, a portion of a lower surface of the second protruding insulating layer TIL2 may be exposed, and the second base electrode BE2 may be provided. The second protruding insulating layer TIL2 may protrude in one direction with respect to the second base electrode BE2.

Next, manufacturing the light-emitting-element layer (S200′) may be performed. Manufacturing the light-emitting-element layer (S200) is different from manufacturing the light-emitting-element layer including the electrode disconnection member (S200), in that forming the electrode disconnection member EDS is not performed.

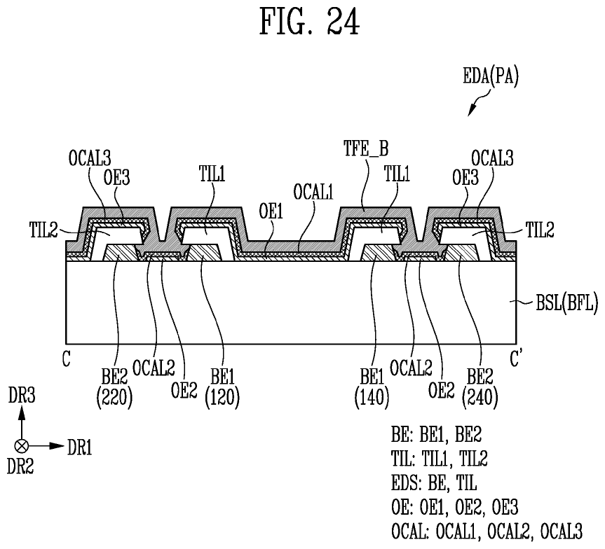

Referring to FIG. 24, the outer electrode portion OE, the outer capping portion OCAL, and the base encapsulation layer TFE_B may be formed.

Referring to FIG. 16, in the present step, the second electrode ELT2 may be formed in the display area DA, and the outer electrode portion OE may be formed in the electrode disconnection area EDA.

Similar to the previous embodiment, the light emitting part EL may be manufactured by a solution process in the display area DA, and then the second electrode ELT2 and the outer electrode portion OE may be deposited without a mask. Accordingly, the outer electrode portion OE may have an electrode structure disconnected by the electrode disconnection member EDS including the base electrode BE and the protruding insulating layer TIL.

In the present step, a portion of the outer electrode portion OE deposited in the electrode disconnection area EDA may be formed between adjacent first base electrodes BE1 to form the first outer electrode portion OE1. Another portion of the outer electrode portion OE deposited in the electrode disconnection area EDA may be formed between the first base electrode BE1 and the second base electrode BE2 to form the second outer electrode portion OE2. Still another portion of the outer electrode portion OE deposited in the electrode disconnection area EDA may be formed outside the second base electrode BE2 to form the third outer electrode portion OE3.

According to an embodiment, the outer capping portion OCAL may be formed in a same process as the capping layer CPL in the display area DA.

According to an embodiment, a portion of the outer capping portion OCAL may be formed on the first outer electrode portion OE1 to form the first outer capping portion OCAL1. Another portion of the outer capping portion OCAL may be patterned on the second outer electrode portion OE2 to form the second outer capping portion OCAL2. Still another portion of the outer capping portion OCAL may be formed outside the second base electrode BE2 to form the third outer capping portion OCAL3.

In the present step, the base encapsulation layer TFE_B may cover the first to third outer capping portions OCAL1, OCAL2, and OCAL3 and may cover a side surface of the base electrode BE.

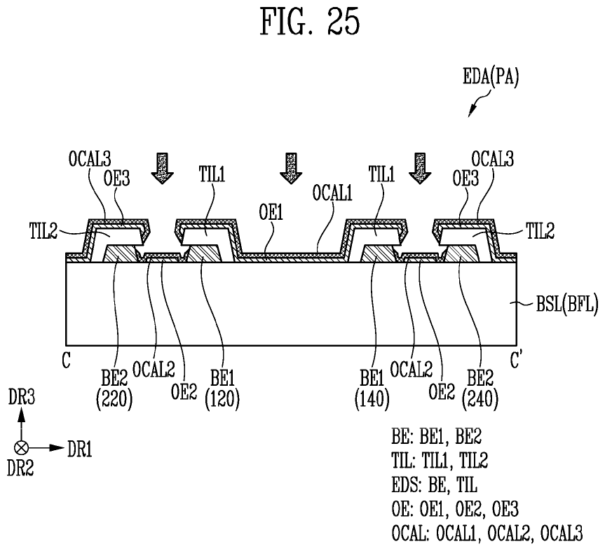

Referring to FIG. 25, the base encapsulation layer TFE_B in the electrode disconnection area EDA may be removed.

In the present step, the base encapsulation layer TFE_B disposed in the electrode disconnection area EDA may be removed, and the outer capping portion OCAL in the electrode disconnection area EDA may be exposed.

Thereafter, additional layers on the light-emitting-element layer LEL may be disposed, and the display device DD according to another embodiment described above with reference to FIGS. 9 to 12 may be manufactured.

As described above, although the present disclosure has been described with reference to the preferred embodiment above, those skilled in the art or those having a common knowledge in the art will understand that the present disclosure may be variously modified and changed without departing from the spirit and technical area of the present disclosure described in the claims which will be described later.

Therefore, the technical scope of the present disclosure should not be limited to the contents described in the detailed description of the specification, but should be defined by the claims.

What is claimed is:

1. A display device comprising:
a base layer including a display area and a peripheral area surrounding at least a portion of the display area;
a light emitting element disposed on the base layer in the display area and including a first electrode, a second electrode, and a light emitting part disposed between the first electrode and the second electrode;
an electrode disconnection member disposed on the base layer in the peripheral area; and
an electrode portion disposed adjacent to the electrode disconnection member,
wherein the electrode disconnection member includes a reverse-taper member and has a shape surrounding an area in a plan view,
wherein the reverse-taper member includes an inner edge facing the area;
wherein the electrode portion includes a first electrode portion disposed in the area and a second electrode portion disposed on an upper surface of the reverse-taper member along the inner edge, and
wherein the first electrode portion and the second electrode portion are physically spaced apart from each other.

2. The display device according to claim 1, further comprising:
an outer capping layer disposed on the electrode portion,
wherein the light emitting element further includes a capping layer disposed on the second electrode and including a same material as the outer capping layer, and
wherein at least a portion of the outer capping layer and the second electrode portion expose at least a portion of the upper surface of the reverse-taper member.

3. The display device according to claim 2, further comprising:
an outer encapsulation layer disposed on the outer capping layer; and
an encapsulation layer disposed on the capping layer in the display area and including a same material as the outer encapsulation layer,
wherein the outer encapsulation layer exposes at least a portion of the upper surface of the reverse-taper member and covers a side surface of the reverse-taper member facing the area.

4. The display device according to claim 1, wherein the electrode disconnection member includes a plurality of electrode disconnection members, and
wherein the plurality of electrode disconnection members form an electrode disconnection area surrounding the display area.

5. The display device according to claim 4, wherein the plurality of electrode disconnection members are sequentially arranged on a first direction and a second direction different from the first direction.

6. A display device comprising:
a base layer including a display area and a peripheral area surrounding at least a portion of the display area;
a light emitting element disposed on the base layer in the display area and including a first electrode, a second electrode, and a light emitting part disposed between the first electrode and the second electrode; and
an electrode disconnection member disposed on the base layer in the peripheral area,
wherein the electrode disconnection member includes a base electrode and a protruding insulating layer disposed on the base electrode,
wherein the base electrode includes a first base electrode and a second base electrode spaced apart each other,
wherein the protruding insulating layer includes a first protruding insulating layer disposed on the first base electrode and a second protruding insulating layer disposed on the second base electrode,
wherein at least a portion of the protruding insulating layer protrudes from the base electrode in a plan view, and
wherein a separation area having a closed-loop structure is formed between the first base electrode and the second base electrode.

7. The display device according to claim 6, wherein the light emitting element further includes a capping layer disposed on the second electrode,
wherein the display device further comprises an encapsulation layer disposed on the capping layer, and
wherein the encapsulation layer is disposed in the display area without being disposed in an electrode disconnection area where the electrode disconnection member is disposed.

8. The display device according to claim 6, further comprising:
a pixel circuit disposed on the base layer,
wherein the base electrode includes a same material as any one of electrodes forming the pixel circuit.

9. The display device according to claim 8, wherein the base electrode is disposed between the protruding insulating layer and the base layer, and
wherein the base electrode includes a conductive material, the protruding insulating layer includes an insulating material, and etching rate of the base electrode and the protruding insulating layer are different from each other.

10. The display device according to claim 6, further comprising:
an outer electrode portion disposed on the protruding insulating layer; and
an outer capping portion disposed on the outer electrode portion,
wherein at least a portion of the outer electrode portion is disposed on an inclined side surface of the protruding insulating layer, and the outer capping portion covers at least a portion of the outer electrode portion disposed on the inclined side surface.

11. A method of manufacturing a display device including a display area and a peripheral area surrounding at least a portion of the display area, the method comprising:
forming a pixel circuit; and
forming a light-emitting-element layer disposed on the pixel circuit and including a light emitting element electrically connected to the pixel circuit,
wherein forming the light-emitting-element layer comprises:
forming a pixel defining layer on a base layer in the display area and a reverse-taper member on the base layer in the peripheral area;
forming a light emitting part in an area surrounded by the pixel defining layer in the display area; and
forming an electrode layer in the display area and the peripheral area,
wherein the reverse-taper member surrounds an area and includes an inner edge facing the area,
wherein the electrode layer includes an electrode portion disposed in the peripheral area, and
wherein the electrode portion comprises:
a first electrode portion disposed in the area; and
a second electrode portion disposed on an upper surface of the reverse-taper member.

12. The method according to claim 11, wherein the forming the light emitting part comprises discharging an organic material for forming the light emitting part by using an inkjet printing method.

13. The method according to claim 11, wherein the forming the pixel defining layer and the forming the reverse-taper member are performed in a same process.

14. The method according to claim 11, wherein the forming the electrode layer comprises separating the first electrode portion and the second electrode portion without using a mask.

15. The method according to claim 11, further comprising:
removing at least a portion of the second electrode portion disposed on the upper surface of the reverse-taper member.

16. A method of manufacturing a display device including a display area and a peripheral area surrounding at least a portion of the display area, the method comprising:
forming a pre-etch base electrode on the base layer in the peripheral area;
forming a protruding insulating layer on the pre-etch base electrode in the peripheral area; and
removing at least a portion of the pre-etch base electrode disposed under the protruding insulating layer.

17. The method according to claim 16, wherein the removing the at least a portion of the pre-etch base electrode comprises a wet etching process.

18. The method according to claim 16, wherein the forming the pre-etch base electrode are performed simultaneously with a forming an electrode in the display area, and
wherein the forming the protruding insulating layer are performed simultaneously with a forming an insulating layer in the display area.

19. The method according to claim 16, further comprising:
forming a light-emitting-element layer in the display area, the light-emitting-element layer including a first electrode, a second electrode, and a light emitting part disposed between the first electrode and the second electrode, and
forming an outer electrode portion in the peripheral area on the protruding insulating layer when forming the second electrode,
wherein the pre-etch base electrode includes a first pre-etch base electrode and a second pre-etch base electrode spaced apart from each other with a separation area interposed therebetween, and
wherein the outer electrode portion includes a first outer electrode portion and a second outer electrode portion physically spaced apart from each other with the protruding insulating layer interposed therebetween.

20. The method according to claim 19, further comprising:
forming an outer capping portion on the outer electrode portion;
forming an outer encapsulation layer on the outer capping portion; and
exposing the outer capping portion by removing the outer encapsulation layer disposed on the outer capping layer.
